(19) United States
(12) Patent Application Publication
(10) Pub. No.: US 2018/0248061 A1
(43) Pub. Date: Aug. 30, 2018

(54) STABLE PEROVSKITE SOLAR CELL

(71) Applicant: Epic Battery Inc., Fremont, CA (US)

(72) Inventor: Melvin James BULLEN, Fremont, CA (US)

(21) Appl. No.: 15/902,961

(22) Filed: Feb. 22, 2018

Related U.S. Application Data
(60) Provisional application No. 62/462,924, filed on Feb. 24, 2017.

(51) Int. Cl. H01L 31/048; H01L 31/032; H02S 50/10

(52) U.S. Cl. CPC H01L 31/0481; H02S 50/10; H01L 31/032

(57) ABSTRACT

Described herein are apparatuses, systems, and methods for a photovoltaic device including a perovskite solar cell with a longer usable lifetime than prior perovskite solar cells. In various embodiments, the photovoltaic device may include a perovskite cell that is at least partially encapsulated by two different encapsulant layers. Such a device may be referred to as a meta-encapsulated perovskite cell. A first encapsulant layer may be on the perovskite cell and may fully or partially encapsulate the perovskite cell. A second encapsulant layer may be on the first encapsulant layer and may fully or partially encapsulate the perovskite cell and/or the first encapsulant layer. Other embodiments may be described and claimed.

### CROSS REFERENCE TO RELATED APPLICATION

The present application claims priority to U.S. Provisional Patent Application No. 62/462,924, filed Feb. 24, 2017, which is hereby incorporated by reference.

### TECHNICAL FIELD

Embodiments herein relate to the field of solar cells, and, more specifically, to stable perovskite solar cells.

### BACKGROUND

Perovskite solar cells use an inexpensive halide-based material as the light-harvesting layer. The perovskite may include calcium, titanium, and oxygen (e.g., (e.g., CaTiO₃). Perovskite solar cells hold an advantage over traditional silicon solar cells in the simplicity of their processing. Silicon cells require an expensive, multistep process, conducted at temperatures greater than 1000° C., in a high vacuum, using a clean room facility. Until a process like this is scaled, the costs are prohibitive. In comparison, a perovskite cell can be manufactured in a kitchen, with simple wet chemistry and inexpensive materials. However, perovskite solar cells have not been adequately stabilized to match the 30-year warranty of silicon-based solar cells.

### BRIEF DESCRIPTION OF THE DRAWINGS

Embodiments will be readily understood by the following detailed description in conjunction with the accompanying drawings and the appended claims. Embodiments are illustrated by way of example and not by way of limitation in the figures of the accompanying drawings.

FIG. 1A illustrates a cross-sectional view of a photovoltaic perovskite device with a fully meta-encapsulated perovskite solar cell, in accordance with various embodiments.

FIG. 1B illustrates a perspective view of a perovskite solar cell that may be meta-encapsulated, in accordance with various embodiments.

FIG. 2 illustrates a close-up view of an electrode wire through the first and second encapsulant of a meta-encapsulated perovskite solar cell, in accordance with various embodiments.

FIG. 3 illustrates a cross-sectional view of a photovoltaic perovskite device that includes a perovskite cell, a first encapsulant layer that partially encapsulates the perovskite cell, and a second encapsulant layer that fully encapsulates the perovskite cell, in accordance with various embodiments.

FIG. 4 illustrates a cross-sectional view of a photovoltaic perovskite device that includes a perovskite cell, a first encapsulant layer that fully encapsulates the perovskite cell, and a second encapsulant layer that partially encapsulates the perovskite cell, in accordance with various embodiments.

FIG. 5 illustrates a cross-sectional view of a photovoltaic perovskite device that includes a perovskite cell, a first encapsulant layer that partially encapsulates the perovskite cell, and a second encapsulant layer that partially encapsulates the perovskite cell, in accordance with various embodiments.

FIG. 6 schematically illustrates a photovoltaic perovskite device including a control circuit coupled to a meta-encapsulated perovskite cell, in accordance with various embodiments.

FIG. 7 illustrates a photovoltaic perovskite device 700 including a control circuit that is encapsulated by the second encapsulant layer, in accordance with various embodiments.

FIG. 8 is a flowchart illustrating aspects of a health assessment process to assess the health of a perovskite solar cell in accordance with various embodiments.

FIG. 9 is a flowchart to illustrate aspects of a health assessment test that may be performed on a perovskite solar cell, in accordance with various embodiments.

FIG. 10 is a flowchart to illustrate a process for normalizing and/or validating a health assessment test in accordance with some embodiments.

FIG. 11 illustrates a perovskite solar cell with a non-planar photovoltaic surface, in accordance with various embodiments.

FIG. 12 illustrates a cross-sectional view of an example of a solar panel 1200 that may implement the meta-encapsulated perovskite solar cells and/or associated techniques, as described herein

### DETAILED DESCRIPTION OF DISCLOSED EMBODIMENTS

In the following detailed description, reference is made to the accompanying drawings, which form a part hereof, and in which are shown by way of illustration embodiments that may be practiced. It is to be understood that other embodiments may be utilized and structural or logical changes may be made without departing from the scope. Therefore, the following detailed description is not to be taken in a limiting sense.

Various operations may be described as multiple discrete operations in turn, in a manner that may be helpful in understanding embodiments; however, the order of description should not be construed to imply that these operations are order-dependent.

The description may use perspective-based descriptions such as up/down, back/front, and top/bottom. Such descriptions are merely used to facilitate the discussion and are not intended to restrict the application of disclosed embodiments.

The terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

For the purposes of the description, a phrase in the form “A/B” or in the form “A and/or B” means (A), (B), or (A and B). For the purposes of the description, a phrase in the form “at least one of A, B, and C” means (A), (B), (C), (A and B), (A and C), (B and C), or (A, B and C). For the purposes of the description, a phrase in the form “(A)B” means (B) or (AB) that is, A is an optional element.

The description may use the terms “embodiment” or “embodiments,” which may each refer to one or more of the same or different embodiments. Furthermore, the terms “comprising,” “including,” “having,” and the like, as used with respect to embodiments, are synonymous, and are generally intended as “open” terms (e.g., the term “including” should be interpreted as “including but not limited to,” the term “having” should be interpreted as “having at least,” the term “includes” should be interpreted as “includes but is not limited to,” etc.).

With respect to the use of any plural and/or singular terms herein, those having skill in the art can translate from the plural to the singular and/or from the singular to the plural as is appropriate to the context and/or application. The various singular/plural permutations may be expressly set forth herein for sake of clarity.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, and so forth.

Described herein are apparatuses, systems, and methods for a photovoltaic device including a perovskite solar cell with a longer usable lifetime than prior perovskite solar cells. In various embodiments, the photovoltaic device may include a perovskite cell that is at least partially encapsulated by two different encapsulant layers. Such a device may be referred to as a meta-encapsulated perovskite cell. A first encapsulant layer may be on the perovskite cell, and a second encapsulant layer may be on the first encapsulant layer. The first encapsulant layer may also be referred to as the inner encapsulant layer, and the second encapsulant layer may also be referred to as the outer encapsulant layer. The first encapsulant layer and second encapsulant layer may both be transparent to enable sunlight to pass through them. For example, the first encapsulant layer and the second encapsulant layer may have a solar transmissivity of 80% or greater, such as a solar transmissivity of 90% or greater.

The perovskite cell may include a perovskite, and anode, and a cathode. The perovskite may form a p-n junction. The perovskite cell may generate a voltage between the anode and the cathode in response to solar energy. The perovskite cell may be a single junction cell, a multi-junction cell, or a tandem cell. A multi-junction cell may include two or more p-n junctions of different materials. A tandem cell may include two or more p-n junctions of the same materials.

In some embodiments, the first and/or second encapsulant layers may fully or partially encapsulate the perovskite cell. By full encapsulation, it is meant that the first or second encapsulant layer surrounds the perovskite cell. Full encapsulation (also referred to as complete encapsulation) as used herein means that no part of the underlying layer (e.g., the photovoltaic perovskite cell) is exposed. It will be understood that in some embodiments one or more electrical wires (e.g., electrical wires connecting to the anode and/or cathode of the perovskite cell) may extend through the first or second encapsulation layers. The penetration of the electrical wires (e.g., the conductive wire and surrounding insulation) does not negate the full encapsulation.

The first or second encapsulant layer that fully encapsulates the perovskite cell may have zero material edges within the layer. A material edge may be defined as an interface between the material of the encapsulant layer with another material in the same layer (e.g., plane).

In some embodiments, one or both of the first and second encapsulant layer may partially encapsulate the perovskite cell with only one material edge. For example, the first encapsulant layer may have one material edge to form two material surfaces, a first material surface that corresponds to the material of the first encapsulant layer and a second material surface that corresponds to a material of the perovskite cell. In one non-limiting example, the second material surface may correspond to the anode of the perovskite cell. That is, the first encapsulant layer may leave at least part of the anode exposed, while covering the remaining portion of the perovskite cell.

Additionally, or alternatively, the second encapsulant layer may partially encapsulate the perovskite cell with only one material edge. For example, the second encapsulant layer may have one material edge to form two material surfaces, one material surface that corresponds to the material of the second encapsulant layer and a second material surface that corresponds to another material (e.g., the material of the first encapsulant layer or a material of the perovskite cell, such as the anode). Material edges may be susceptible to moisture intrusion. Accordingly, limiting the material edges of the first and/or second encapsulant layer to zero or one material edge may prevent moisture from penetrating to the perovskite cell.

In various embodiments, the materials of the first encapsulant layer and the second encapsulant layer may have different material properties. For example, the first encapsulant layer may have a lower permeability to moisture than the second encapsulant layer. Additionally, or alternatively, the second encapsulant layer may have a higher tensile strength and/or flexural strength than the first encapsulant layer. For example, in some embodiments, the first encapsulant layer may have a moisture vapor transmission rate of less than 0.1 grams per square meter per day (g/m²/day). Additionally, or alternatively, the second encapsulant layer may have a tensile strength of greater than 2,000 pounds per square inch, such as a tensile strength greater than 5,000 pounds per square inch. Together, the first and second encapsulant layers create an environment for the photovoltaic perovskite cell that is highly waterproof, while also being strong and durable. Accordingly, the photovoltaic perovskite cell may have a longer usable lifetime than prior perovskite cells.

The first and/or second encapsulant layers may include any suitable material or materials with the desired properties. For example, in some embodiments, the first encapsulant layer may include polychlorotrifluoroethylene (PCTFE), a fluoropolymer resin, polyethylene terephthalate (PET), polysiloxanes (e.g., silicone), and/or ethyl vinyl acetate (EVA). Additionally, or alternatively, the second encapsulant layer may include polycarbonate and/or glass. If the second encapsulant layer includes glass, the glass may be a low iron glass (e.g., having an iron oxide content of less than 0.02%). Glass containing less iron oxide has a higher solar transmissivity than traditional soda lime glass (e.g., about 91% compared with about 85%), thereby providing greater efficiency for the perovskite cell. Low iron glass is more expensive to produce than traditional soda lime glass, but the higher solar transmissivity justifies the expense.

In some embodiments, the first and second encapsulant layers may provide unusual Fickian behavior, which is beneficial for waterproofing the perovskite cell. The unusual behavior is an extended time for the second (outer) encapsulant to reach moisture equilibrium prior to penetrating the first (inner) encapsulant. For example, silicone is a material that appears to be less permeable to water than EVA, however due to the complexities of Fick's second law, silicone is superior to EVA as a water barrier.

In various embodiments, a transparent adhesive may be disposed between the first and second encapsulant layers. Additionally, or alternatively, a surfactant may be disposed on an outer surface of the second encapsulant layer. The surfactant may prevent scratches or other deformations in the second encapsulant layer. The surfactant may also introduce anti-reflection properties, thereby improving the performance of the perovskite cell.

Also described herein is a health assessment circuit coupled to the perovskite cell. The health assessment circuit may determine the health of the perovskite cell (e.g., to determine whether moisture has invaded the perovskite cell and degraded performance). The health assessment circuit may energize the perovskite cell electrically and measure the resulting electrostatic response of the perovskite cell. For example, the health assessment circuit may apply a potential, such as 3.2 volts, 5 volts, or another suitable value, to the perovskite cell anode. The health assessment circuit may measure the electrostatic response (e.g., electrostatic voltage and/or current) at the cathode of the perovskite cell (e.g., that is generated through the perovskite cell from the anode to the cathode). The health assessment circuit may determine the health of the perovskite cell based on the measured voltage. For example, a higher electrostatic voltage than a previous measurement may be an indication of moisture invasion.

The Shockley-Queisser (S-Q) limit refers to the maximum theoretical efficiency of a single p-n junction to generate photovoltaic power. The S-Q theory limits the efficiency of perovskite solar cells to 31%. This compares favorably with silicon at 32%, and gallium arsenide, 33%. Gallium arsenide is rare, and ultra-pure silicon expensive to make. The techniques described herein may extend the usable life of perovskite cells, making them a desirable alternative to other types of solar cells. Additionally, at the end of its useful life, the perovskite cell may be completely recycled, and reused.

Another benefit of perovskites is that they are translucent, making multi-junction and/or tandem cells possible. For example, perovskite cells may be combined into tandem cells to harvest light over the visible spectrum, e.g., red, burnt yellow-orange, green, blue, etc. A multi-junction and/or tandem cell may increase the efficiency of the perovskite cell (e.g., with a theoretical limitation of 68% efficiency).

Additionally, the colors of perovskite cells may have aesthetic appeal. Different color perovskite cells may have different efficiencies. However, some applications may be suitable for using a lower efficiency perovskite cell in order to have a desired color. In some embodiments, the perovskite itself may be a shade of gray or black, and any color may be provided by the anode. The anode may be any suitable material, such as copper, silver, or doped carbon fiber. Other anode materials may be possible. When carbon fiber is chosen, the color is very dark (black). If silver or copper is used, then colors become possible. Some example colors are translucent red, translucent umber, translucent green, and/or translucent blue. It will be apparent that numerous other colors and efficiencies are possible.

Furthermore, perovskite cells may be formed in many different shapes, such as planar, a curved planar shape, a clothoid curve (e.g., clothoid spiral), an open cylindrical shape, a closed spherical shape, an egg shape, etc. A clothoid curve has its curvature change linearly with its curve length. Mathematically then, the curvature of a clothoid curve is equal to the reciprocal of the radius of that curve. French curves are types of clothoid curves and represent esthetically pleasing shapes.

Accordingly, the meta-encapsulated perovskite cell described herein may be formed with many different shapes and/or form factors, and may be used for several different intended uses. For example, the meta-encapsulated perovskite cell may be used in an outdoor solar panel (e.g., a planar panel) for generation of electricity, similar to traditional solar panels. However, the meta-encapsulated perovskite cell may also be incorporated into other devices, such as a standard commercial battery (e.g., 9-volt, button, AAAA, AAA, AA, C, 6-volt, D, etc.), a charger for consumer electronics, a lamp, a powered speaker, a clock, a vehicle (e.g., car), etc. In some embodiments, the device may include a rechargeable battery coupled to the perovskite cell to store electrical energy harvested by the perovskite cell.

Additionally, or alternatively, the device may include control circuitry coupled to the perovskite cell. The control circuitry may, for example, keep solar power generation on the maximum power point, perform battery management, etc. The control circuitry may additionally or alternatively include the moisture detection circuit described herein. In some embodiments, the control circuitry and/or moisture detection circuit may be encapsulated by the second encapsulant layer. For example, the control circuitry may be potted circuitry.

In some embodiments, the photovoltaic perovskite device may include one or more additional encapsulant layers in addition to the first and second encapsulant layers. For example, the photovoltaic perovskite device may include one or more encapsulant layers between the perovskite cell and the first encapsulant layer, between the first and second encapsulant layers, and/or outside the second encapsulant layer (e.g., on the outer surface of the second encapsulant layer). The one or more additional encapsulant layers may fully or partially encapsulate the perovskite cell.

In one non-limiting example, the first encapsulant layer may include PCTFE and the second encapsulant layer may include low iron glass (e.g., for a solar panel). In another non-limiting example, the first encapsulant layer may include siloxane (e.g., silicone) and the second encapsulant layer may include polycarbonate (e.g., for a solar battery). In yet another non-limiting example, a meta-encapsulated perovskite cell may include three encapsulation layers, such as a layer of PCTFE on the perovskite cell, a layer of silicone on the layer of PCTFE, and a layer of low iron glass on the layer of silicone. Such a three-layer encapsulation may be particularly suitable for automobiles, however such a device may also be used in other applications. It will be apparent that numerous other arrangements of the meta-encapsulated perovskite cell are contemplated by the embodiments described herein.

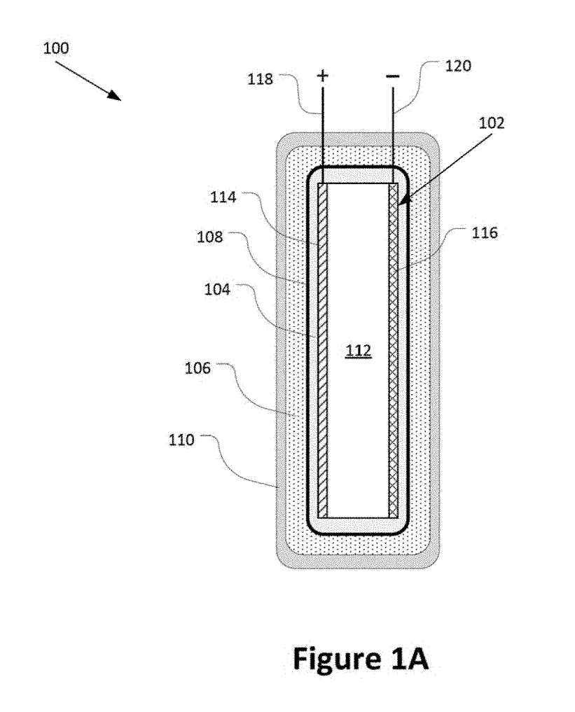

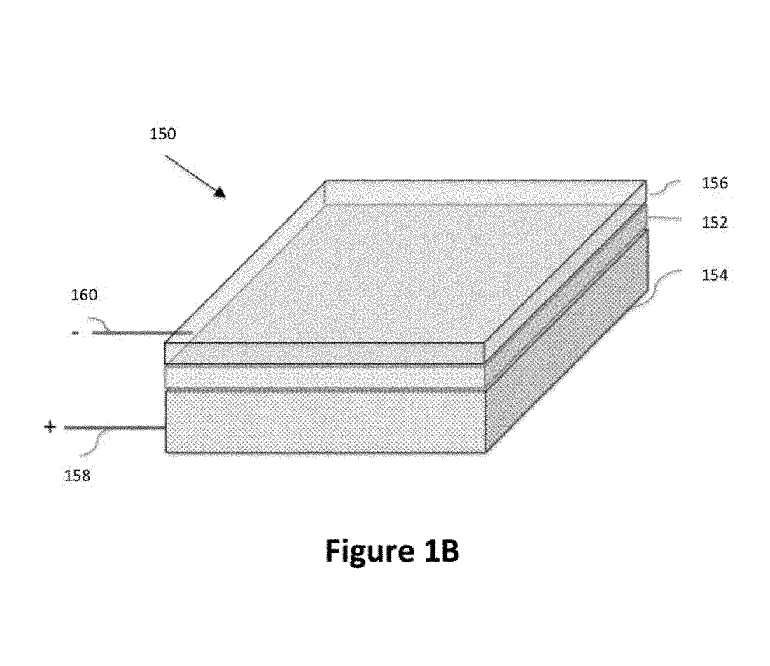

FIG. 1A illustrates a cross-sectional view of a photovoltaic device 100 with fully meta-encapsulated perovskite solar cell, in accordance with various embodiments. The device 100 includes a perovskite cell 102, a first encapsulant layer 104, and a second encapsulant layer 106. The first encapsulant layer 104 is disposed on the perovskite cell 102 and fully encapsulates the perovskite cell 102. The second encapsulant layer 106 is disposed on the first encapsulant layer 104 and fully encapsulates the perovskite cell 102 and the first encapsulant layer. Accordingly, the first encapsulant layer 104 and the second encapsulant layer 106 provide a layer around the perovskite cell 106 with no material edges and one material surface (the surface of the respective encapsulant layer 104 or 106).

In some embodiments, an adhesive 108 (e.g., a transparent adhesive) may be disposed between the first encapsulant layer 104 and the second encapsulant layer 106. Additionally, or alternatively, some embodiments of the device 100 may include a surfactant 110 on the outer surface of the second encapsulant layer 106. The surfactant may prevent scratches or other deformations in the second encapsulant layer 106.

In various embodiments, the perovskite cell 102 may include a perovskite 112, an anode 114, and a cathode 116. The anode 114 and cathode 116 may be on opposite sides of the perovskite 112, as shown in FIG. 1A, although other configurations are possible. The device 100 may further include an anode wire 118 and a cathode wire 120 that are coupled to the anode 114 and cathode 116, respectively, of the perovskite cell 102.

The anode 114 and/or cathode 116 may include any suitable materials. For example, in some embodiments, the anode 114 may include doped carbon fiber, copper, silver, and/or another suitable material. Additionally, or alternatively, the cathode 116 may include a transparent ceramic conductor, such as indium tin oxide (ITO), fluorine doped tin oxide (FTO), and/or another transparent conducting material. The anode wire 118 and cathode wire 120 may include a conductor inside a protective sheath. In some embodiments, the anode wire 118 and cathode wire 120 may extend from the perovskite cell 102 through the first encapsulant layer 104 and second encapsulant layer 106, as shown.

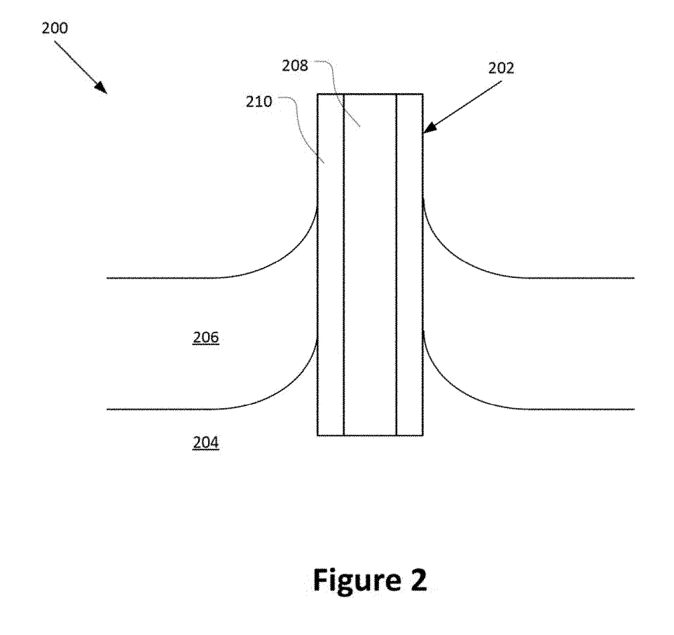

In some embodiments, the second encapsulant layer 106 may form a concave meniscus around the anode wire 112 and/or cathode wire 114 to provide resistance to intrusion of moisture. For example, FIG. 2 shows an expanded view of a portion of a perovskite photovoltaic device 200 that includes a wire 202, a first encapsulant layer 204, and a second encapsulant layer 206. As shown in FIG. 2, both the first encapsulant layer 204 and second encapsulant layer 206 may form a concave meniscus around the wire 202. In other embodiments, only one of the first encapsulant layer 204 or second encapsulant layer 206 may form a concave meniscus around the wire. The wire 206 may include a conductor 208 inside a protective sheath 210, as shown.

Referring again to FIG. 1A, as discussed above, the first encapsulant layer 104 and/or second encapsulant layer 106 may include any suitable material or materials with the desired properties. For example, in some embodiments, the first encapsulant layer 104 may include polychlorotrifluoroethylene (PCTFE), a fluoropolymer resin, and/or ethyl vinyl acetate (EVA). Additionally, or alternatively, the second encapsulant layer 106 may include polycarbonate and/or low iron glass. Both the first encapsulant layer 104 and the second encapsulant layer 106 may be transparent. For example, the first encapsulant layer 104 and the second encapsulant layer 106 may have a solar transmissivity equal to or greater than glass. In one embodiment, the first encapsulant layer 104 and the second encapsulant layer 106 may have a solar transmissivity of 80% or greater, such as a solar transmissivity of 90% or greater. The first encapsulant layer 104 may be highly waterproof (e.g., with a permeability to moisture of below 0.1). In some embodiments, the first encapsulant layer 104 may have a lower permeability to moisture than the second encapsulant layer 106. Additionally, or alternatively, the second encapsulant layer 106 may be stronger (e.g., in tensile strength and/or flexural strength) than the first encapsulant layer 104. For example, the second encapsulant layer may have a tensile strength of greater than 10,000 pounds per square inch.

The device 100 may be formed by any suitable process. For example, in some embodiments, the first encapsulant layer 104 and/or second encapsulant layer 106 may be applied to the perovskite cell 102 in liquid form and heat compressed to harden around the perovskite cell 102. In some embodiments, a closed tube of the material of the first encapsulant layer 104 may be heat compressed to tightly fit to the perovskite cell 102. A second closed tube of the material of the second encapsulant layer 106 may be heat affixed to the first encapsulant layer 104, using transparent adhesive 108 for adhesion. In embodiments that include the surfactant 110, the surfactant may be applied, for example, by dip coating or another suitable method. The manufacturing method may prevent pinholes from forming in the first encapsulant layer 104 and/or second encapsulant layer 106, which may otherwise be a source of moisture intrusion.

In some embodiments, the second encapsulant layer 106 may be formed around the perovskite cell 102 using microelectromechanical systems (MEMS) techniques and/or nanotechnology to join two or more portions of the second encapsulant layer 106. For example, surfaces of the material of second encapsulant layer 106 that are to be joined may be prepared for bonding by etching or another suitable process and then joined together to form a strong and watertight bond.

FIG. 1B illustrates a perspective view of a perovskite solar cell 150, in accordance with various embodiments. The perovskite solar cell 150 may include a perovskite 152, an anode 154, a cathode 156, an anode wire 158 coupled to the anode 154, and a cathode wire 160 coupled to the cathode 156. Although not shown in FIG. 1B, the perovskite solar cell 150 may be meta-encapsulated by a first encapsulant layer and a second encapsulant layer, as described herein. For example, the perovskite solar cell 150 may correspond to perovskite cell 102 of the device 100 in some embodiments.

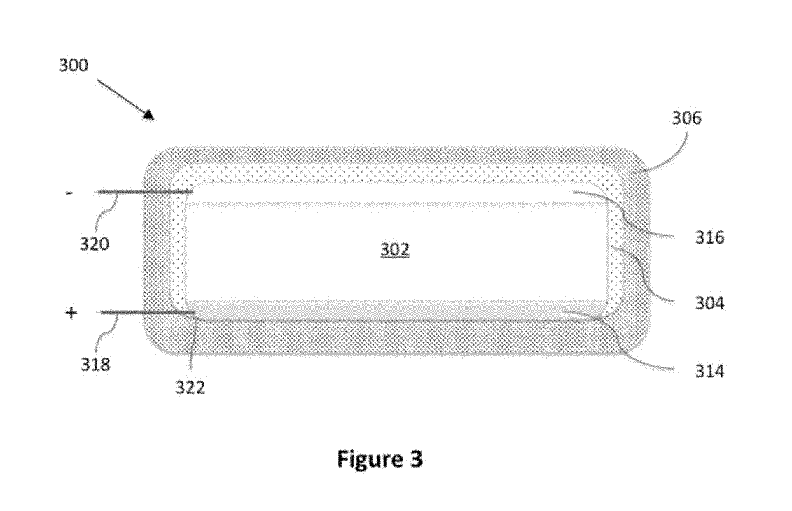

FIG. 3 illustrates a cross-sectional view of a photovoltaic perovskite device 300 that includes a perovskite cell 302, a first encapsulant layer 304 that partially encapsulates the perovskite cell 302, and a second encapsulant layer 306 that fully encapsulates the perovskite cell 302. The perovskite cell 302 may include a perovskite 312, an anode 314, and a cathode 316. Additionally, an anode wire 318 coupled to the anode 314 and a cathode wire 320 coupled to the cathode 316. Although not shown in FIG. 3, in some embodiments the device 300 may further include an adhesive between the first encapsulant layer 304 and the second encapsulant layer 306 and/or a surfactant on the outer surface of the second encapsulant layer 306. In various embodiments, the first encapsulant layer 304 may have one material edge 322 to form two material surfaces: the outer surface of the first encapsulant layer 304 and the outer surface of the anode 314. In some embodiments, the anode 314 may be formed of a material (e.g., doped carbon fiber, oxygen free copper, or ultrafine silver) that are all highly waterproof. Accordingly, the perovskite 312 may be protected from moisture incursion even though the first encapsulant layer 304 is only partially encapsulating the perovskite cell 302.

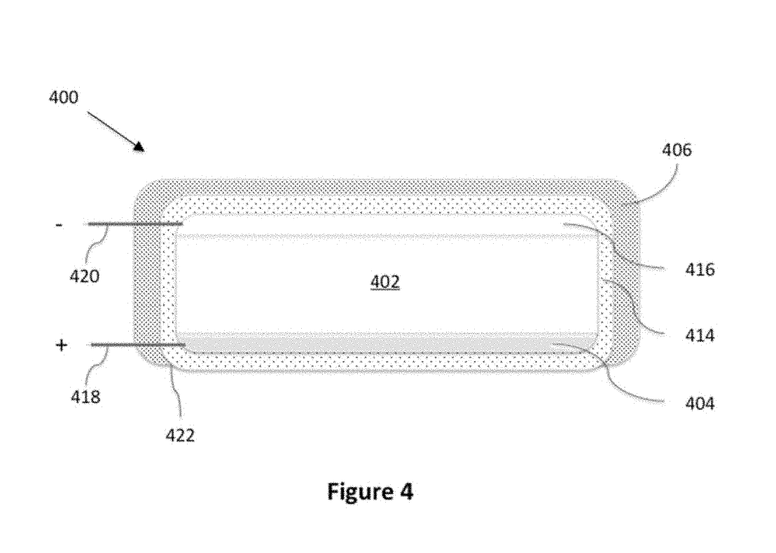

FIG. 4 illustrates a photovoltaic perovskite device 400 that includes a perovskite cell 402, a first encapsulant layer 404 that fully encapsulates the perovskite cell 402, and a second encapsulant layer 406 that partially encapsulates the perovskite cell 402. The perovskite cell 402 may include a perovskite 412, an anode 414, and a cathode 416. Additionally, an anode wire 418 coupled to the anode 414 and a cathode wire 420 coupled to the cathode 416. Although not shown in FIG. 4, in some embodiments the device 400 may further include an adhesive between the first encapsulant layer 404 and the second encapsulant layer 406 and/or a surfactant on the outer surface of the second encapsulant layer 406. In various embodiments, the second encapsulant layer 406 may have one material edge 424 to form two material surfaces: the outer surface of the second encapsulant layer 406 and the outer surface of the first encapsulant layer 404.

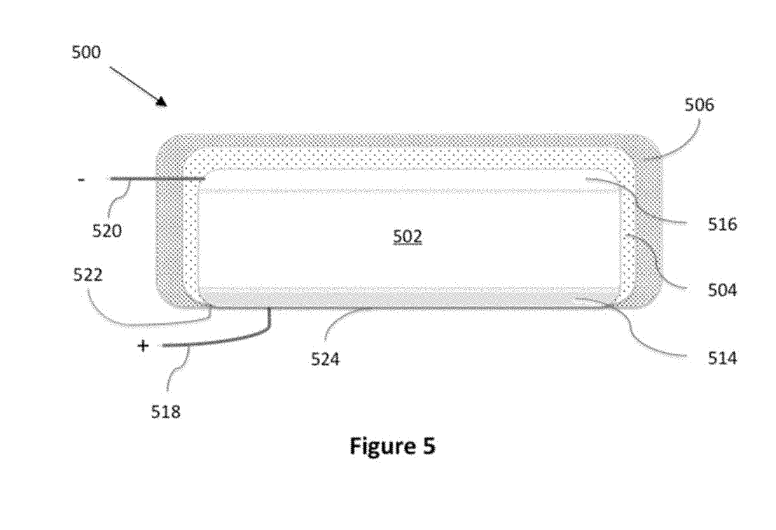

FIG. 5 illustrates a photovoltaic perovskite device 500 that includes a perovskite cell 502, a first encapsulant layer 504 that partially encapsulates the perovskite cell 502, and a second encapsulant layer 506 that partially encapsulates the perovskite cell 502. The perovskite cell 502 may include a perovskite 512, an anode 514, and a cathode 516. Additionally, an anode wire 518 coupled to the anode 514 and a cathode wire 520 coupled to the cathode 516. Although not shown in FIG. 5, in some embodiments the device 500 may further include an adhesive between the first encapsulant layer 504 and the second encapsulant layer 506 and/or a surfactant on the outer surface of the second encapsulant layer 506. In various embodiments, the first encapsulant layer 504 may have one material edge 522 to form two material surfaces: the outer surface of the first encapsulant layer 504 and the outer surface of the anode 514. Additionally, the second encapsulant layer 506 may have one material edge 524 to form two material surfaces: the outer surface of the second encapsulant layer 506 and the outer surface of the first encapsulant layer 504.

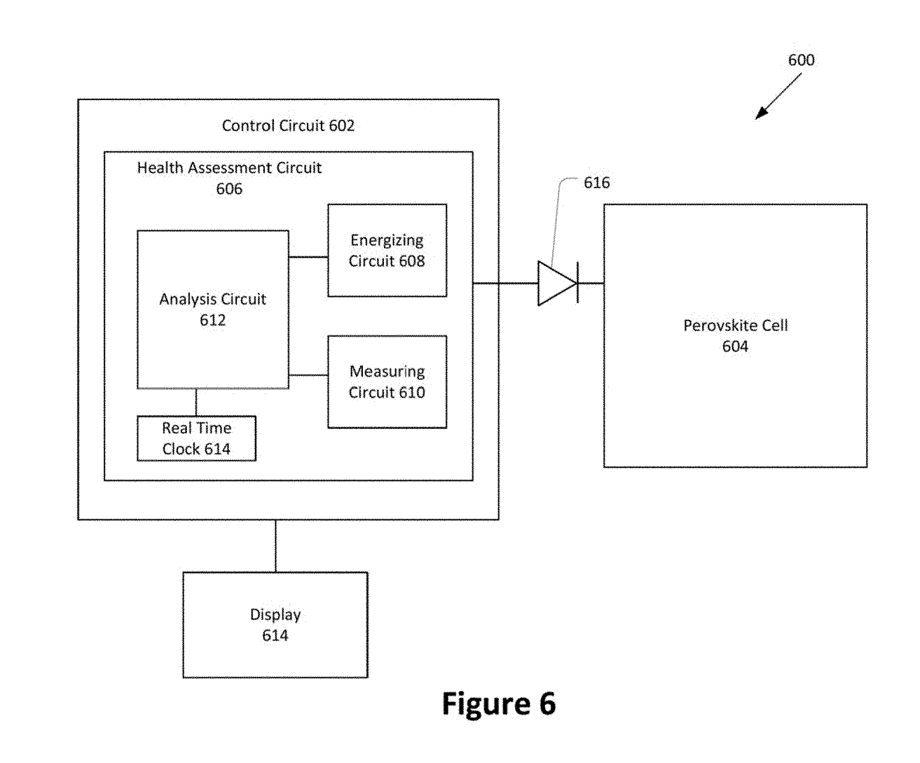

FIG. 6 schematically illustrates a photovoltaic perovskite device 600 including a control circuit 602 coupled to a meta-encapsulated perovskite cell 604, in accordance with various embodiments. The meta-encapsulated perovskite cell 604 may correspond to any of the meta-encapsulated perovskite cells described herein, such as the devices 100, 200, 300, 400, and/or 500. In some embodiments, the control circuit may be at least partially encapsulated in the first encapsulant layer and/or second encapsulant layer of the meta-encapsulated perovskite cell 604.

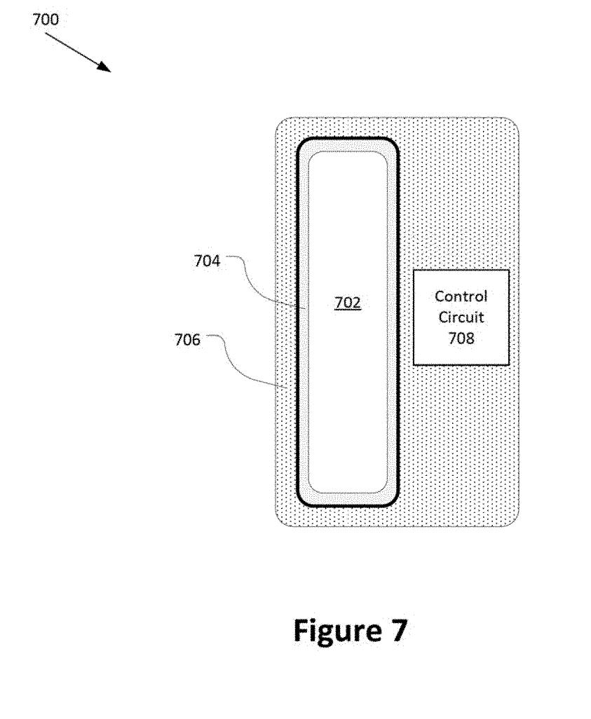

For example, FIG. 7 illustrates a photovoltaic perovskite device 700 including a perovskite cell 702, a first encapsulant layer 704, and a second encapsulant layer 706. A control circuit 708 is disposed outside the first encapsulant layer 704 and fully encapsulated by the second encapsulant layer 706. In other embodiments, the control circuit 708 may be partially or fully encapsulated by the first encapsulant layer 704. For example, the control circuit 708 may be “potted” circuitry.

Referring again to FIG. 6, the control circuit 602 may include a health assessment circuit 606 to determine the health of the perovskite cell 604 (e.g., periodically or upon request). The health assessment circuit 606 may include an energizing circuit 608, a measuring circuit 610, an analysis circuit 612, and/or a real-time clock 614. As part of a health assessment process, the energizing circuit 608 may energize the perovskite cell 604 to generate a voltage across the electrodes (anode and cathode) of the perovskite cell 604. For example, the energizing circuit 608 may use electricity from a battery to energize the perovskite cell 604.

The measuring circuit 610 may measure the resulting electrostatic response (e.g., voltage and/or current) of the perovskite cell 604. In some embodiments, the energizing circuit 608 applies a predetermined voltage (e.g., 3.2 volts, 5 volts, or another suitable value) to the anode of the perovskite cell, and the measuring circuit 610 measures the voltage at the cathode of the perovskite cell.

The analysis circuit 612 may receive the value of the measured voltage from the measuring circuit 610, and may determine the health of the perovskite cell 604 based on the value of the measured voltage. For example, a higher value of the measured voltage may be associated with lower health of the perovskite cell 604 (e.g., due to moisture). In some embodiments, the analysis circuit 612 may compare the value of the measured voltage to one or more thresholds that correspond to one or more health levels of the perovskite cell 604. Alternatively, the analysis circuit 612 may perform a calculation based on the measured voltage to obtain a health level (e.g., a numerical value, such as a percentage) for the perovskite cell 604.

In some embodiments, the analysis circuit 612 may cause the determined health level to be displayed on a display 614 of the device 600. Additionally, or alternatively, the analysis circuit 612 may transmit the determined health of the perovskite cell 604 to an external device, such as a wired or wireless communication device (e.g., a computer, database, smartphone, etc.). In some embodiments, the analysis circuit 612 may trigger an alarm or other action if the determined health is below a threshold.

In various embodiments, the control circuit 602 and/or health assessment circuit 606 may be coupled to the perovskite cell 604 via a diode 616 to protect the control circuit 602 and/or health assessment circuit 606 from damage due to solar-generated voltage in the perovskite cell 604.

In some embodiments, the health assessment circuit 606 may perform the health assessment process periodically. For example, the real time clock 614 may manage a timer to indicate when the analysis circuit 612 should initiate the health assessment process.

Additionally, or alternatively, the health assessment circuit 606 may not be able to make an accurate health assessment if the perovskite cell 604 is generating solar power. For example, in some embodiments, the perovskite cell 606 may generate a voltage across the electrodes while generating solar power that is several orders of magnitude larger than the voltage generated across the electrodes by the health assessment circuit 606 (e.g., millivolts compared with nanovolts). Accordingly, in some embodiments, the health assessment circuit 606 may determine whether the perovskite cell 604 is generating solar power (e.g., using a power detection circuit, which may be implemented by the measuring circuit 610 or separate circuitry of the health assessment circuit 606), and may not proceed with the health assessment process if the perovskite cell 604 is generating solar power. For example, the analysis circuit 612 may reset the timer managed by the real time clock 614, and may initiate the health assessment process again after expiration of the timer.

In some embodiments, the analysis circuit 612 may send an indicator to the display 614 and/or an external device to indicate that the health assessment process was aborted. This may enable an operator of the device 600 to prevent the perovskite cell 604 from producing solar power (e.g., by covering the perovskite cell 604 and/or moving the perovskite cell 604 out of the sunlight). Additionally, or alternatively, in some embodiments, the health assessment circuit 606 may schedule the health assessment process to occur at night when it is less likely that the perovskite cell 604 will be producing solar power.

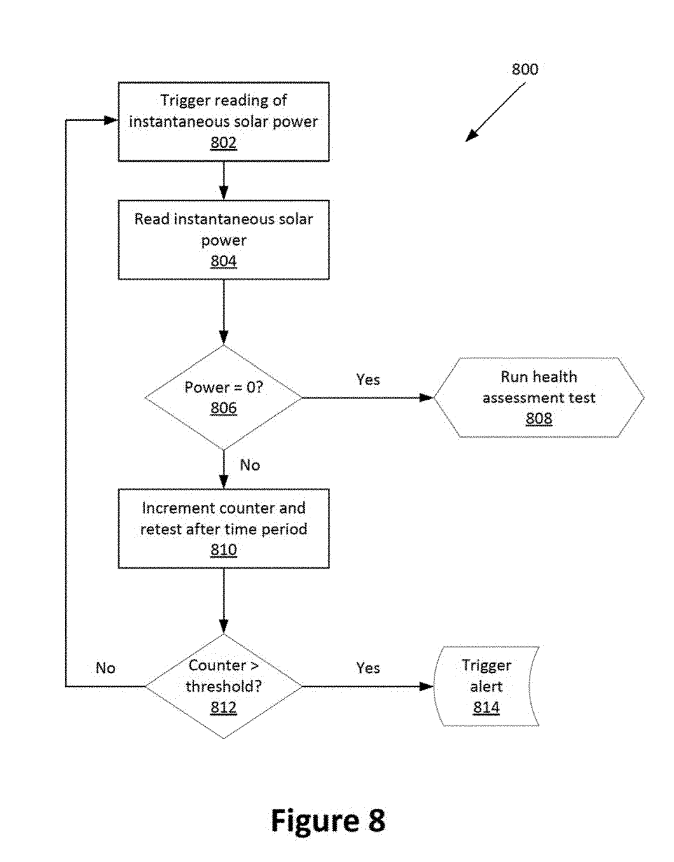

FIG. 8 is a flowchart illustrating aspects of a health assessment process 800 to assess the health of a perovskite solar cell in accordance with various embodiments. The health assessment process 800 may be performed by a health assessment circuit, such as the health assessment circuit 606 in some embodiments. Additionally, the health assessment process 800 may be performed on any suitable perovskite solar cell, such as any of the meta-encapsulated perovskite solar cells described herein.

At 802 of the process 800, the health assessment circuit may trigger a reading of the instantaneous solar power generated by the perovskite cell. The reading may be triggered, for example, by the real time clock 614. The reading may be triggered based on any suitable conditions, such as expiration of a timer, receipt of a request from a user, or according to a test schedule.

At 804 of the process 800, the health assessment circuit may read the instantaneous solar power being generated by the perovskite cell. At 806, the health assessment circuit may determine whether the instantaneous solar power is zero. If the instantaneous solar power is zero (no power is being generated), then the health assessment circuit proceeds to run the health assessment test at 808.

If the instantaneous solar power is determined not to be zero (solar power is being generated), then, at 810 of the process 800, the health assessment circuit may increment a counter and reset a timer to retest whether instantaneous solar power is being generated after expiration of the timer. At 812, the health assessment circuit may determine whether the value of the counter is greater than a threshold. If the value of the counter is greater than a threshold, then the health assessment circuit may trigger an alert at 814. The triggered alert may cause an alert to be displayed on the display 614 and/or sent to a remote device and/or remote application. The alert may enable an operator to take action to prevent the perovskite cell from generating solar power (e.g., by covering it or moving it to a darker location) to enable the health assessment test to proceed.

If the counter is not greater than the threshold, then the health assessment circuit may restart the process 800 at 802 after expiration of the timer.

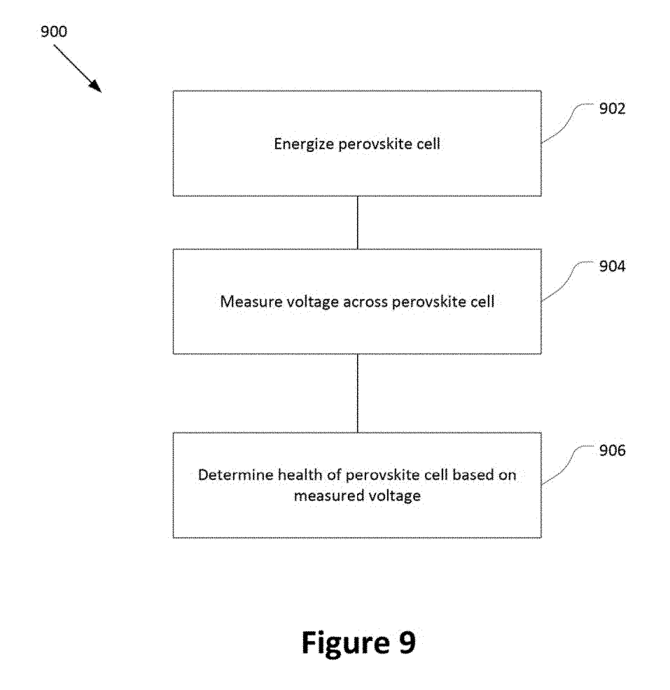

FIG. 9 is a flowchart to illustrate aspects of a health assessment test 900 that may be performed on a perovskite solar cell, in accordance with various embodiments. The health assessment test 900 may correspond to the health assessment test triggered at 808 of process 800. The health assessment test 900 may be performed by a health assessment circuit, such as health assessment circuit 606.

At 902 of the health assessment test 900, the health assessment circuit may energize the perovskite cell. At 904 of the health assessment test 900, the health assessment circuit may measure a voltage across the perovskite cell (e.g., between the electrodes). At 906 of the health assessment test 900, the health assessment circuit may determine the health of the perovskite cell based on the measured voltage. The health assessment circuit may take one or more actions based on the determined health of the perovskite cell, such as storing the value in a database and/or triggering an alarm (e.g., if the determined health is poorer than a threshold). For example, in some embodiments, the health assessment circuit may record the measured voltage, the temperature, the date, the model number of the device with the perovskite cell, and/or the serial number of the device with the perovskite cell.

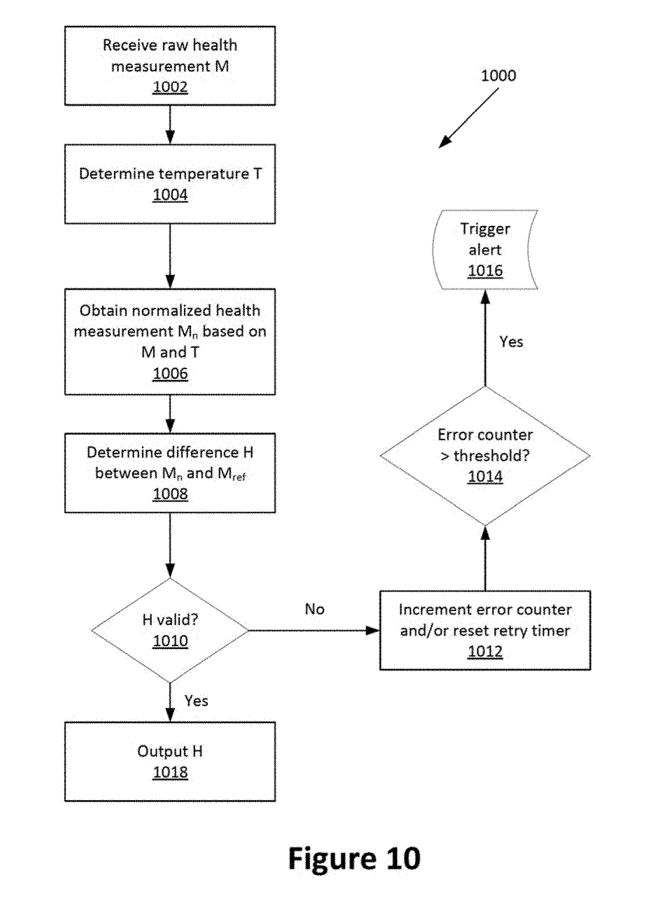

FIG. 10 is a flowchart to illustrate a process 1000 for normalizing and/or validating a health assessment test (e.g., the health assessment test 900) in accordance with some embodiments. The process 1000 may be performed by a health assessment circuit, such as health assessment circuit 606.

At 1002 of the process 1000, a raw health measurement M is received. The raw health measurement may be stored and time stamped. In some embodiments, the raw health measurement M may correspond to the voltage measured across the perovskite cell during the health assessment test. At 1004, the temperature Tat which the measurement was taken is determined. At 1006, the health measurement M is normalized using the determined temperature T and a reference temperature Tref (e.g., the temperature when a reference measurement was taken) to obtain a normalized health measurement Mn. For example, the normalized health measurement Mn may be determined according to Mn=M c (Tree/T²), where c is a constant (e.g., derived by factory testing). M and Mn may be in nanovolts, and T and Tref may be in degrees Celsius.

In some embodiments, if the value of the measured temperature T is less than a threshold, then the threshold may be used for the value T in determining the normalized health measurement. For example, in some embodiments, the threshold may be 2 degrees Celsius, so that if the measured temperature is less than 2 degrees Celsius, a value of 2 will be used for T in determining the normalized health measurement. The effects of temperature on the health measurement may stop below the threshold (e.g., 2 degrees Celsius). Additionally, or alternatively, there may be a maximum temperature above which the perovskite cell should not be operated (e.g., 68 degrees Celsius or another suitable value based upon testing).

At 1008 of the process 1000, a health value H is determined that is the difference between a reference value Mref (e.g., reference voltage) and the normalized health measurement Mn. The reference value Mref may correspond to an acceptable or expected value of the measured voltage across the perovskite cell at the reference temperature when the perovskite cell is in full health (e.g., no moisture penetration). Accordingly, the health value D may correspond to the health of the perovskite cell. In one non-limiting example, the reference value Mref may be about 20 nanovolts.

At 1010, it is determined whether the health value H is valid. The value H may be invalid, for example, if H is so large (e.g., above a threshold) that it indicates that the perovskite cell made solar energy during the measurement interval. The perovskite cell may generate solar energy when exposed to moonlight in some embodiments. If H is determined to be invalid, then, at 1012, the process 1000 may increment an error counter and/or reset the retry timer to restart the health assessment process (e.g., the process 800 and/or 900) after expiration of the retry timer.

At 1014 of the process 1000, it may be determined whether the error counter has exceeded an error threshold. If so, then an alert may be triggered at 1016.

If it is determined at 1010 that the value H is valid, then the value H may be output at 1018 of the process 100. The value H may be stored into memory and/or another action may be taken (e.g., display to the user or trigger of an alarm as appropriate).

Table 1 below indicates one example of potential values for the health value H and a corresponding qualitative health and operational efficiency (as a percentage compared with full health). The expected years after which the perovskite cell will have the corresponding value of H are also listed. It will be apparent that the values listed in Table 1 are merely examples, and that other errors can occur to make the health of the perovskite cell deteriorate more or less quickly than listed in Table 1. The estimated years refer to a possible perovskite solar panel with a first encapsulant of PCTFE and a second encapsulant of low iron glass.

TABLE 1

| H (microvolts) | Health | % Efficiency |
|---|---|---|
| H < 0.04 | Perfect | >95 |
| 0.04 ≤ H < 0.08 | Excellent | >90 |
| 0.08 ≤ H < 0.16 | Good | >80 |
| 0.16 ≤ H < 0.32 | Poor | >70 |
| 0.32 ≤ H ≤ 1.00 | End of Life | <60 |

In some embodiments, some or all of the information depicted in FIG. 2 may be displayed on the display of the device including the perovskite cell (e.g., the display 614) and/or on a remote device. The display may use colors, graphs, pie charts, numerical values, or other visual indicators to convey the information and/or trends over time.

As discussed above, if the value H is too large (e.g., greater than 1.00 microvolts), it may be assumed that the perovskite cell was generating energy from the sun or another light source, which swamped out the voltage caused by the health assessment circuit. There are concerns the perovskite behavior is non-linear at an end of life situation, and operational testing must be done to ensure that a determined value of H is not discarded (a false negative) when in fact the measurement might represent actual moisture invasion. In some embodiments, the confidence in the validity of the value H may be determined based on historical data.

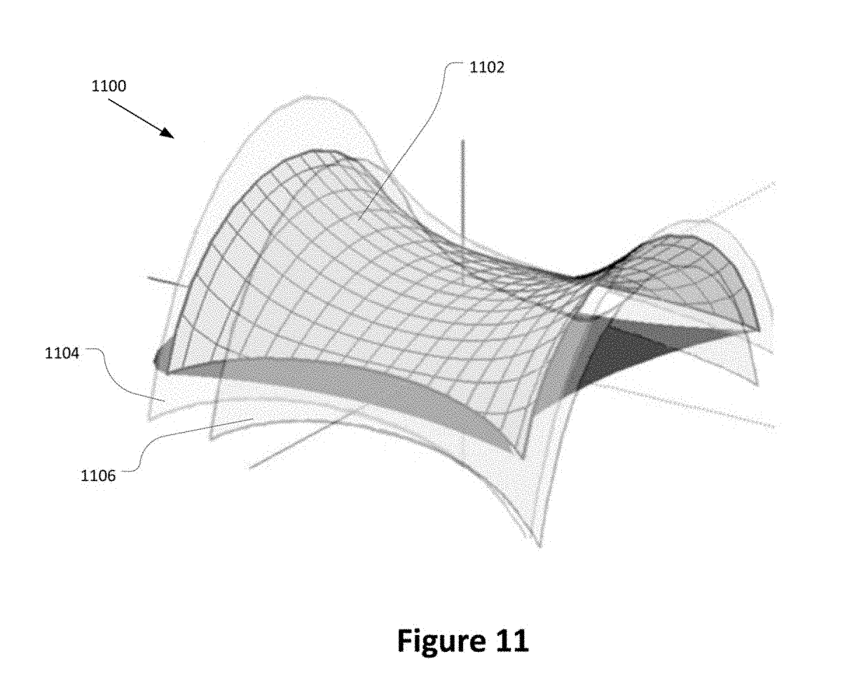

FIG. 11 shows a photovoltaic perovskite device 1100 with a perovskite solar cell 1102 having a photovoltaic surface that is non-planar. For example, the perovskite solar cell 1102 has a saddle shaped photovoltaic surface. The device 1100 further includes a first (inner) encapsulant layer 1104 and a second (outer) encapsulant layer 1106. The outer encapsulant layer 1106 is shown peeled back to better illustrate the different layers. As discussed herein, the first encapsulant layer 1104 and second encapsulant layer may fully or partially encapsulate the perovskite solar cell 1102. It will be apparent that other shapes of the perovskite solar cell 1102 are possible, such as a closed tube, a sphere, an egg with a flat bottom surface, etc.

A discussion is provided below of the theoretical moisture penetration and therefore the lifetime and solar efficiency for a perovskite solar cell meta-encapsulated as described herein. This is derived from a Fickian solution to the law of diffusion in two dimensions. Given that the meta-encapsulation consists of two different transparent polymers, one might assume moisture invasion for each polymer to be a straightforward Fickian, but it is not. Depending upon the relationship between the diffusion potential D and the sorption potential S of the two layers you could have unusual Fickian behavior that aided or delayed moisture invasion.

Solutions for the unusual Fickian behavior have been formulated by considering that diffusion occurs because of a disturbance to an equilibrium state, characterized by the chemical potential of the diffusing substance p. The diffusion potential then, is p and sorbed molecules move with macroscopic velocity ux, under a driving force dp/dx. This driving force is against the frictional resistance of the solid medium, measured by a frictional coefficient f_{T}. This is expressed with the diffusion potential, −RT/D_{T} (du/dx). Stating this mathematically:

Jₓ=kuₓ=−(k/f_{T})(dμ/dx)=−(kD_{T}/RT)(dμ/dx).

The friction coefficient is changed due to the thermodynamic diffusion potential D_{T}. This is D, in Fick's equations. Jₓ must be expressed in terms of a sorbed penetrant G, defined by: μ=μₒ+RTlogₑ(G). Where μₒ denotes an initial thermodynamic state that is measured. Our penetrant G is moisture. Jₓ then becomes:

Jₓ=−D_{T}k(d logₑG/dx)=−D_{T}S(dG/dx)=−P(dG/dx).

Here a new thermodynamic equilibrium parameter, the sorption potential S=k/G is introduced, and the permeability coefficient is written: P=DTS.

The value of G, and hence of S, for any given k, is determined with a penetrant, (in this case water, or Gw), defined below. μₒ is operationally measured.

μ_{w}=μₒ+RT logₑ(Gw).

This irreversible thermodynamic approach demonstrates the important role of the sorption coefficient S in diffusion processes. As moisture invades the outer encapsulation layer from micro-abrasions or the anode/cathode wire, it tends to balloon at the inner encapsulation layer and build up concentration, until it can overcome the highly moisture resistant inner encapsulation layer. With the right inner encapsulant, It may take decades for moisture to finally invade the inner encapsulation layer, and begin the process of working through to the perovskite.

As described herein, the diffusion potential (Dₑ₁) of the first encapsulant may be smaller (e.g., much smaller) than the diffusion potential of the second encapsulant (Dₑ₂). Additionally, the sorbative function (Sₑ₂) of the second encapsulant, e.g., the tendency of moisture invasion to follow the path of least resistance, may be greater than the diffusion potential Dₑ₁ of the first encapsulant. Accordingly, it is thermodynamically easier for moisture to continue to invade the second encapsulant than for the moisture to invade the first encapsulant. That is, the permeability coefficient (Pₑ₁) of the first encapsulant layer is less than the permeability coefficient of the second encapsulant layer (Pₑ₂).

Therefore, moisture may collect at the interface between the first and second encapsulants, thereby delaying moisture invasion of the first encapsulant (and the perovskite solar cell). Additionally, once the thermodynamic concentration of moisture in the second encapsulant allows penetration into the first encapsulant, the moisture will not move into the first encapsulant in large volume. Incursion into the second encapsulant still requires the thermodynamic barrier of the inner encapsulant to be overcome.

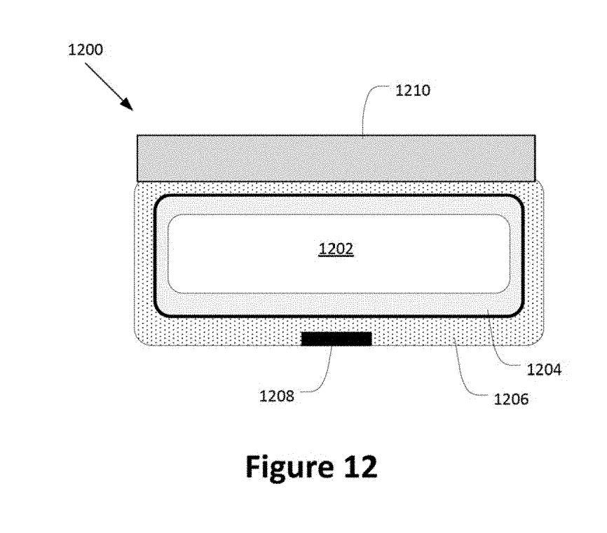

FIG. 12 illustrates one example of a solar panel 1200 that may implement the meta-encapsulated perovskite solar cells and/or associated techniques, as described herein. Solar panel 1200 includes a perovskite solar cell 1202, a first encapsulant 1204 surrounding the perovskite solar cell 1202, and a second encapsulant 1206 surrounding the first encapsulant 1204 and the perovskite solar cell 1202. The perovskite solar cell 1202 may be a multi-junction cell and/or a tandem cell in some embodiments. In some embodiments, the second encapsulant layer 1206 may be asymmetrical around the perovskite solar cell 1202 (e.g., thicker below the perovskite solar cell 1202 than above the perovskite solar cell 1202). For example, in one non-limiting example, the second encapsulant layer 1206 may be about 1.5 mm thick above the perovskite solar cell 1202 and about 6 mm thick below the perovskite solar cell 1202. As a further non-limiting example, the first encapsulant layer 1204 may have a thickness of less than 1 mm (e.g., about 0.3 mm), and/or the perovskite solar cell 1202 may have a thickness of a fraction of a mm to 5 mm, such as about 3 mm.

The solar panel 1200 may further include an electrical interface 1208 to receive electrical power generated by the perovskite solar cell 1202. For example, the electrical interface 1208 may be coupled to the anode and/or cathode of the perovskite solar cell 1202. The electrical interface 1208 may provide an alternating current (AC) or direct current (DC) output signal.

In some embodiments, the solar panel 1200 may further include an anti-reflecting metallic glass 1210 on the top surface of the second encapsulant layer 1206. In one non-limiting example, the glass 1210 may be about 5 mm thick. The interface between the glass 1210 and the second encapsulant layer 1206 may be a micro-electro-mechanical system (MEMS), in which the surfaces are prepared (e.g., etched) and then set together, resulting in a strong bond, and a watertight seal.

In some embodiments, the bottom portion of the second encapsulant layer 1206 may be bonded to the other portion of the second encapsulant layer and to the first encapsulant layer by MEMS interfaces. Such a technique may be used, for example, if the second encapsulant layer is formed of glass, such as an anti-reflective low iron glass.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope. Those with skill in the art will readily appreciate that embodiments may be implemented in a very wide variety of ways. This application is intended to cover any adaptations or variations of the embodiments discussed herein. Therefore, it is manifestly intended that embodiments be limited only by the claims and the equivalents thereof.

What is claimed is:

1. A photovoltaic device comprising:
a perovskite cell;
a first encapsulant layer on the perovskite cell, wherein the first encapsulant layer includes a first material that is transparent and has a moisture vapor transmission rate of below 0.1 grams per square meter per day, and wherein the first encapsulant layer includes zero material edges or one material edge to form two material surfaces including the first material and a material of the perovskite cell; and
a second encapsulant layer on the first encapsulant layer, wherein the second encapsulant layer includes a second material that is transparent, and wherein the second encapsulant layer includes zero material edges or one material edge to form two material surfaces including the second material.

2. The photovoltaic device of claim 1, wherein the first encapsulant layer includes zero material edges such that the first material completely encapsulates the perovskite cell.

3. The photovoltaic device of claim 2, wherein the second encapsulant layer includes zero material edges such that the second material completely encapsulates the perovskite cell.

4. The photovoltaic device of claim 2, wherein the second encapsulant layer includes one material edge to form two material surfaces including the second material and the first material.

5. The photovoltaic device of claim 1, wherein the first encapsulant layer includes one material edge to form two material surfaces.

6. The photovoltaic device of claim 5, wherein the second encapsulant layer includes one material edge to form two material surfaces.

7. The photovoltaic device of claim 6, wherein the material of the perovskite cell corresponds to an anode of the perovskite cell, and wherein the two material surfaces of the second encapsulant layer include the second material and the material of the perovskite cell.

8. The photovoltaic device of claim 5, wherein the second encapsulant layer includes zero material edges such that the second material completely encapsulates the perovskite cell.

9. The photovoltaic device of claim 1, wherein the second material has a tensile strength of greater than 2,000 pounds per square inch.

10. The photovoltaic device of claim 1, wherein the second material has a higher permeability to moisture than the first material.

11. The photovoltaic device of claim 1, further comprising an anode wire and a cathode wire coupled to the perovskite cell and extending through the first and second encapsulant layers.

12. The photovoltaic device of claim 1, further comprising a transparent adhesive between the first encapsulant layer and the second encapsulant layer.

13. The photovoltaic device of claim 1, further comprising a surfactant on the second encapsulant layer.

14. The photovoltaic device of claim 1, wherein the first encapsulant layer is a polysiloxane, a polychlorotrifluoroethylene (PCTFE) resin or an ethyl vinyl acetate resin, and wherein the second encapsulant layer is a transparent polycarbonate resin or a low iron glass.

15. The photovoltaic device of claim 1, further comprising a health assessment circuit comprising:
an energizing circuit to energize the perovskite cell to generate a voltage in the perovskite cell;
a measuring circuit to measure the generated voltage; and
an analysis circuit to determine a health of the photovoltaic device based on the measured voltage.

16. The photovoltaic device of claim 15, wherein energizing circuit, measuring circuit, and analysis circuit are to perform the respective generate, measure, and determine operations as part of a health assessment process, wherein the health assessment circuit further comprises a power detection circuit to determine whether the perovskite cell is producing instantaneous power and trigger the health assessment process responsive to a determination that the perovskite cell is not producing instantaneous power.

17. The photovoltaic device of claim 16, wherein, responsive to a determination that the perovskite cell is producing instantaneous power, the power detection circuit is to start a timer and repeat the determination whether the perovskite cell is producing instantaneous power upon expiration of the timer.

18. The photovoltaic device of claim 15, wherein the analysis circuit is to cause display of the determined health on a local display associated with the photovoltaic device or to send an indication of the determined health to a remote application.

19. The photovoltaic device of claim 1, wherein the perovskite cell is a tandem perovskite cell.

20. The photovoltaic device of claim 1, wherein the perovskite cell is non-planar.

21. A photovoltaic device comprising:
a perovskite cell;
a first material that completely surrounds the perovskite cell, wherein the first material has a solar transmissivity of greater than 90% and a permeability to moisture of less than 0.1; and
a second material that completely surrounds the first material, wherein the second material has a solar transmissivity of over 90% and a tensile strength of greater than 2,000 pounds per square inch.

22. The photovoltaic device of claim 21, wherein the second material has a higher permeability to moisture than the first material.

23. The photovoltaic device of claim 21, further comprising an anode wire and a cathode wire coupled to the perovskite cell and extending through the first and second encapsulant layers.

24. The photovoltaic device of claim 21, further comprising a transparent adhesive between the first encapsulant layer and the second encapsulant layer.

25. The photovoltaic device of claim 21, further comprising a surfactant on the second encapsulant layer.

26. The photovoltaic device of claim 21, wherein the first encapsulant layer is a polychlorotrifluoroethylene resin or an ethyl vinyl acetate resin, and wherein the second encapsulant layer is a transparent polycarbonate resin or a low iron glass.

27. The photovoltaic device of claim 21, further comprising a health assessment circuit comprising:
an energizing circuit to energize the perovskite cell, thereby generating a voltage in the perovskite cell;
a measuring circuit to measure the generated voltage; and
an analysis circuit to determine a health of the photovoltaic device based on the measured voltage.

28. The photovoltaic device of claim 27, wherein energizing circuit, measuring circuit, and analysis circuit are to perform the respective generate, measure, and determine operations as part of a health assessment test, wherein the moisture detection circuit further comprises a power detection circuit to determine whether the perovskite cell is producing instantaneous power and trigger the health assessment test responsive to a determination that the perovskite cell is not producing instantaneous power.

29. The photovoltaic device of claim 28, wherein, responsive to a determination that the perovskite cell is producing instantaneous power, the power detection circuit is to start a timer and repeat the determination whether the perovskite cell is producing instantaneous power upon expiration of the timer.
